(19) United States
(12) Patent Application Publication
(10) Pub. No.: US 2021/0198416 A1
(43) Pub. Date: Jul. 1, 2021

(54) PHOTOSENSITIVE RESIN COMPOSITION, CURED FILM, LAMINATE, MEMBER FOR TOUCH PANEL, AND METHOD FOR MANUFACTURING CURED FILM

(71) Applicant: TORAY INDUSTRIES, INC., TOKYO (JP)

(72) Inventors: Mika Koshino, Otsu-shi, Shiga (JP); Miki Nakamichi, Otsu-shi, Shiga (JP); Mitsuhito Suwa, Otsu-shi, Shiga (JP)

(73) Assignee: TORAY INDUSTRIES, INC., TOKYO (JP)

(21) Appl. No.: 15/779,197

(22) PCT Filed: Dec. 16, 2016
(86) PCT No.: PCT/JP2016/087622

§ 371 Date: May 25, 2018

(30) Foreign Application Priority Data
Dec. 25, 2015 (JP) 2015-253479

(51) Int. Cl. C08G 59/36; C08K 5/521; G03F 7/085; G03F 7/027

(52) U.S. Cl. CPC C08G 59/36; C08K 5/521; G06F 3/041; G03F 7/027; G03F 7/085

(57) ABSTRACT

A photosensitive resin composition contains (A) an ethylenically unsaturated group- and carboxyl group-containing photoreactive resin, (B) an epoxy compound, (C) a polyfunctional epoxy compound, and (D) a photopolymerization initiator.

### CROSS REFERENCE TO RELATED APPLICATIONS

This is the U.S. National Phase application of PCT/JP2016/087622, filed Dec. 16, 2016, which claims priority to Japanese Patent Application No. 2015-253479, filed Dec. 25, 2015, the disclosures of these applications being incorporated herein by reference in their entireties for all purposes.

### TECHNICAL FIELD OF THE INVENTION

The present invention relates to a photosensitive resin composition, a cured film, a member for a touch panel, and a method for manufacturing a cured film.

### BACKGROUND OF THE INVENTION

At present, capacitive touch panels are used in many of smartphones and tablet terminals. In general, sensor substrates of capacitive touch panels have a structure that includes a glass substrate and wires produced by patterning with indium tin oxide (ITO) or a metal (such as silver, molybdenum, or aluminum) on the glass substrate, and also includes an insulating film, and a protective film for protecting ITO and metals at an intersection between the wires. In general, the protective film is often formed from high-hardness inorganic SiO₂, SiNx, transparent photosensitive material or the like, and the insulating film is often formed from a transparent photosensitive material.

Touch panels are broadly divided into out-sell type touch panels having a touch panel layer between a cover glass and a liquid crystal panel, one glass solution (OGS) type touch panels having a touch panel layer directly formed on a cover glass, on-sell type touch panels having a touch panel layer on a liquid crystal panel, and in-sell type touch panels having a touch panel layer inside a liquid crystal panel. In recent years, on-sell type touch panels are actively developed since they can be manufactured in a simpler process than before. Since on-sell type touch panels have a touch panel layer directly formed on a liquid crystal panel, it is necessary to form the wiring material and the protective film and insulating film materials at a low temperature equal to or lower than the heat resistance temperature of the liquid crystal.

However; formation of a film of an inorganic material such as SiO₂ or SiNx by chemical vapor deposition (CVD) requires a high temperature, and it is difficult to apply inorganic materials to on-sell type touch panels. Moreover, conventional transparent photosensitive materials need to be cured at a temperature of 200° C. or higher, and a transparent photosensitive material cured at a low temperature is insufficient in chemical resistance (see, for example, Patent Document 1). Therefore, there is a need for a patternable transparent photosensitive material that is curable at low temperatures and is excellent in chemical resistance and substrate adhesiveness.

As a transparent photosensitive material, a UV-curable coating composition containing an alkali-soluble polymer, a monomer, a photopolymerization initiator, and other additives is known. Such a composition is used not only in overcoat materials for color filters and spacer materials but also in color resists further containing a coloring agent (see, for example, Patent Document 2). The composition is also used in a wide range of applications such as interlayer insulating films, solder resists, and partition walls for display devices (see, for example, Patent Documents 3 and 4).

As a technique for improving the properties of the composition, in Patent Documents 1 to 4, a polyfunctional epoxy compound, a cardo resin, an acrylate compound having an epoxy group, and a compound having an epoxy group or an oxetanyl group are respectively studied, and it is suggested that substrate adhesiveness and chemical resistance are improved.

### PATENT DOCUMENTS

Patent Document 1: Japanese Patent Laid-open Publication No. 2013-76821

Patent Document 2: International Publication No. 2012/176694

Patent Document 3: Japanese Patent Laid-open Publication No. 2015-110765

Patent Document 4: International Publication No. 2015/133162

### SUMMARY OF THE INVENTION

In an on-sell type touch panel, a process at a low temperature of 150° C. or lower is essential since the liquid crystal has low heat resistance. Materials requiring curing at 230° C. or higher as in Patent Documents 1 and 2 do not have sufficient chemical resistance and substrate adhesiveness in low temperature curing at 150° C. Further, it is difficult to satisfy both patternability and properties of the cured film with the materials of Patent Documents 3 and 4.

An object of the present invention is to provide a patternable transparent photosensitive material that is curable at low temperatures and is excellent in chemical resistance and substrate adhesiveness.

The present inventors have found that the object of the present invention can be achieved by a photosensitive resin composition containing a photoreactive resin containing an ethylenically unsaturated group and a carboxyl group, a specific epoxy compound, a specific polyfunctional epoxy compound, and a photopolymerization initiator.

That is, the photosensitive resin composition of the present invention contains (A) a photoreactive resin containing an ethylenically unsaturated group and a carboxyl group, (B) an epoxy compound represented by the following general formula (1), (C) a polyfunctional epoxy compound represented by the following general formula (2), and (D) a photopolymerization initiator:

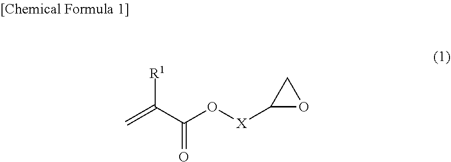

wherein X represents a group having an alkylene oxide having 4 to 10 carbon atoms or a group derived from a bisphenol, and R¹ represents a hydrogen atom or a methyl group;

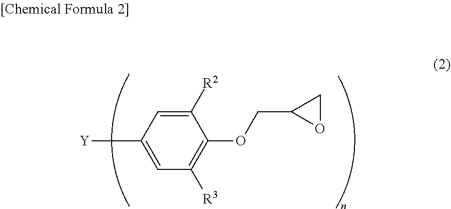

wherein a linking group Y represents a hydrocarbon group having 1 to 15 carbon atoms, R² and R³ each independently represent a hydrogen atom or a hydrocarbon group having 1 to 6 carbon atoms, and n represents an integer of 3 or 4.

The object of the present invention can be achieved by a cured film that is a cured product of the photosensitive resin composition.

The object of the present invention can be achieved by a laminate including a base material and the cured film on the base material.

The object of the present invention can be achieved by member for a touch panel including the laminate.

The object of the present invention can be achieved by a method for manufacturing a cured film, including the steps of applying the photosensitive resin composition to a base material, and heating the photosensitive resin composition at 80 to 150° C. in this order.

The photosensitive resin composition of the present invention is excellent in patternability, is curable at a low temperature of 150° C. or lower, and is capable of providing a cured film having satisfactory chemical resistance and substrate adhesiveness.

### BRIEF DESCRIPTION OF THE DRAWINGS

FIGS. 1a to 1c are each a schematic top view of a touch panel member after each step in the manufacture thereof.

FIG. 2 is a schematic cross-sectional view showing a touch panel member.

### DETAILED DESCRIPTION OF EMBODIMENTS OF THE INVENTION

The photosensitive resin composition of the present invention contains (A) a photoreactive resin containing an ethylenically unsaturated group and a carboxyl group, (B) an epoxy compound represented by the general formula (1), (C) a polyfunctional epoxy compound represented by the general formula (2), (D) a photopolymerization initiator, and (E) a phosphorus-containing compound.

[(A) Photoreactive Resin]

The photosensitive resin composition of the present invention contains (A) a photoreactive resin containing an ethylenically unsaturated group and a carboxyl group (hereinafter also referred to as (A) a photoreactive resin). The ethylenically unsaturated group enables the photosensitive resin composition to exhibit negative photosensitivity, and the carboxyl group enables the photosensitive resin composition to be developed in an alkali aqueous solution.

The photoreactive resin (A) may be, for example, (A-1) a cardo resin containing an ethylenically unsaturated group and a carboxyl group (hereinafter also referred to as (A-1) a cardo resin) or (A-2) an acrylic resin containing an ethylenically unsaturated group and a carboxyl group (hereinafter also referred to as (A-2) an acrylic resin). Preferable examples of the photoreactive resin are listed below, but the photoreactive resin is not limited thereto.

Examples of the cardo resin (A-1) include a cardo resin having two or more structures represented by the following formula (3) as repeating units and containing an ethylenically unsaturated group and a carboxyl group. The photoreactive resin (A) is preferably the cardo resin (A-1) from the viewpoint that it has high photocurability and is excellent in chemical resistance.

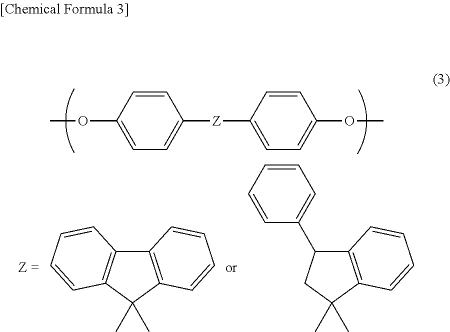

The cardo resin (A-1) can be obtained, for example, by reacting a reaction product of an epoxy compound and a radical polymerizable group-containing basic acid compound with an acid dianhydride.

The catalyst used in the polyaddition reaction and the addition reaction is not limited, and examples thereof include ammonium catalysts such as tetrabutylammonium acetate, amine catalysts such as 2,4,6-tris(dimethylaminomethyl)phenol and dimethylbenzylamine, phosphorus catalysts such as triphenylphosphine, and chromium catalysts such as chromium acetylacetonate and chromium chloride.

Examples of the epoxy compound include the following compounds.

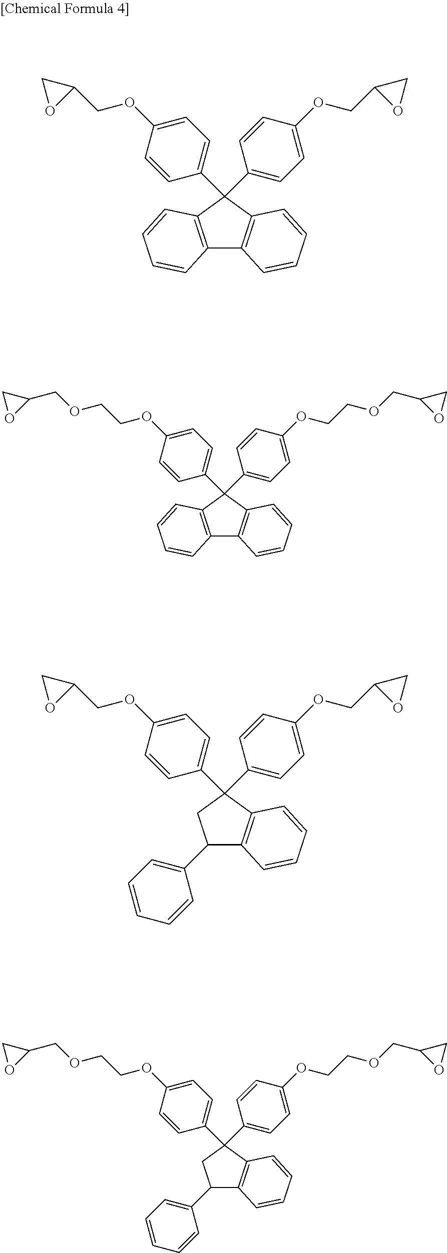 [SMILES: c1ccc2c(c1)-c1ccccc1C2(c1ccc(OCC2CO2)cc1)c1ccc(OCC2CO2)cc1 ; c1ccc2c(c1)-c1ccccc1C2(c1ccc(OCCOCC2CO2)cc1)c1ccc(OCCOCC2CO2)cc1 ; c1ccc(C2CC(c3ccc(OCC4CO4)cc3)(c3ccc(OCC4CO4)cc3)c3ccccc32)cc1 ; c1ccc(C2CC(c3ccc(OCCOCC4CO4)cc3)(c3ccc(OCCOCC4CO4)cc3)c3ccccc32)cc1]

Examples of the radical polymerizable group-containing basic acid compound include (meth)acrylic acid, mono(2-(meth)acryloyloxyethyl)succinate, mono(2-(meth)acryloyloxyethyl)phthalate, mono(2-(meth)acryloyloxyethyl)tetrahydrophthalate, and p-hydroxystyrene.

Examples of the acid dianhydride include aromatic tetracarboxylic dianhydrides such as pyromellitic dianhydride, 3,3′,4,4′-biphenyltetracarboxylic dianhydride, 2,3,3′,4-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 2,2-bis(3,4-dicarboxyphenyl)hexafluoropropane dianhydride, 2,2-bis(2,3-dicarboxyphenyl)hexafluoropropane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)sulfone dianhydride, bis(3,4-dicarboxyphenyl)ether dianhydride, 1,2,5,6-naphthalenetetracarboxylic dianhydride, 2,3,6,7-naphthalenetetracarboxylic dianhydride, 2,3,5,6-pyridinetetracarboxylic dianhydride, and 3,4,9,10-perylenetetracarboxylic dianhydride; and aliphatic tetracarboxylic dianhydrides such as butanetetracarboxylic dianhydride, cyclobutanetetracarboxylic dianhydride, 1,2,3,4-cyclopentanetetracarboxylic dianhydride, cyclohexanetetracarboxylic dianhydride, bicyclo[2.2.1.]heptanetetracarboxylic dianhydride, bicyclo[3.3.1.]tetracarboxylic dianhydride, bicyclo[3.1.1.]hept-2-ene tetracarboxylic dianhydride, bicyclo[2.2.2.]octanetetracarboxylic dianhydride, and adamantanetetracarboxylic dianhydride. In order to improve the chemical resistance of the cured film, pyromellitic dianhydride, 3,3′,4,4′-biphenyltetracarboxylic dianhydride, 2,3,3′,4-biphenyltetracarboxylic dianhydride, and 2,2′,3,3′-biphenyltetracarboxylic dianhydride are preferable.

Part of the acid dianhydride may be replaced with an acid anhydride for the purpose of adjusting the molecular weight. Examples of the acid anhydride include succinic anhydride, maleic anhydride, itaconic anhydride, phthalic anhydride, trimellitic anhydride, pyromellitic monoanhydride, 2,3-biphenyldicarboxylic anhydride, 3,4-biphenyldicarboxylic anhydride, hexahydrophthalic anhydride, glutaric anhydride, 3-methylphthalic anhydride, norbornene dicarboxylic anhydride, cyclohexene dicarboxylic anhydride, and 3-trimethoxysilyl propyl succinic anhydride.

For the cardo resin (A-1), a commercially available product can be preferably used, and examples thereof include “WR-301 (trade name)” (manufactured by ADEKA Corporation), “V-259ME (trade name)” (manufactured by NIPPON STEEL & SUMIKIN CHEMICAL CO., LTD.), and “OGSOL CR-TR1 (trade name)”, “OGSOL CR-TR2 (trade name)”, “OGSOL CR-TR3 (trade name)”, “OGSOL CR-TR4 (trade name)”, “OGSOL CR-TR5 (trade name)”, and “OGSOL CR-TR6 (trade name)” (all manufactured by Osaka Gas Chemicals Co., Ltd.).

For the acrylic resin (A-2), for example, it is possible to use an acrylic resin containing an ethylenically unsaturated group and a carboxyl group, which is obtained by radically polymerizing an unsaturated carboxylic acid and an ethylenically unsaturated compound to give a resin having carboxyl groups, and then causing an addition reaction of an epoxy compound having an ethylenically unsaturated double bond group to part of the carboxyl groups for esterification.

The catalyst for the radical polymerization is not particularly limited, and azo compounds such as azobisisobutyronitrile and organic peroxides such as benzoyl peroxide are generally used.

The catalyst used in the addition reaction of the epoxy compound having an ethylenically unsaturated double bond group is not particularly limited, and known catalysts can be used. Examples thereof include amino catalysts such as dimethylaniline, 2,4,6-tris(dimethylaminomethyl)phenol, and dimethylbenzylamine; tin catalysts such as tin(II) 2-ethylhexanoate and dibutyltin laurate; titanium catalysts such as titanium(IV) 2-ethylhexanoate; phosphorus catalysts such as triphenylphosphine; and chromium catalysts such as chromium acetylacetonate and chromium chloride.

Examples of the unsaturated carboxylic acid include (meth)acrylic acid, itaconic acid, crotonic acid, maleic acid, fumaric acid, and vinylacetic acid.

Examples of the ethylenically unsaturated compound include unsaturated carboxylic acid alkyl esters such as methyl (meth)acrylate, ethyl (meth)acrylate, n-propyl (meth)acrylate, isopropyl (meth)acrylate, n-butyl (meth)acrylate, sec-butyl (meth)acrylate, isobutyl (meth)acrylate, tert-butyl (meth)acrylate, n-pentyl (meth)acrylate, 2-hydroxyethyl (meth)acrylate, and benzyl (meth)acrylate; aromatic vinyl compounds such as styrene, p-methylstyrene, o-methylstyrene, m-methylstyrene, and α-methylstyrene; unsaturated carboxylic acid aminoalkyl esters such as aminoethyl acrylate; unsaturated carboxylic acid glycidyl esters such as glycidyl (meth)acrylate; carboxylic acid vinyl esters such as vinyl acetate and vinyl propionate; vinyl cyanide compounds such as (meth)acrylonitrile and α-chloroacrylonitrile; aliphatic conjugated dienes such as 1,3-butadiene or isoprene; and polystyrene, polymethyl acrylate, polymethyl methacrylate, polybutyl acrylate, polybutyl methacrylate and the like each having a (meth)acryloyl group at the terminal.

Examples of the epoxy compound having an ethylenically unsaturated double bond group include glycidyl (meth)acrylate, α-ethylglycidyl (meth)acrylate, α-n-propylglycidyl (meth)acrylate, α-n-butylglycidyl (meth) acrylate, 3,4-epoxybutyl (meth)acrylate, 3,4-epoxyheptyl (meth)acrylate, α-ethyl-6,7-epoxyheptyl (meth)acrylate, allyl glycidyl ether, vinyl glycidyl ether, o-vinylbenzyl glycidyl ether, m-vinylbenzyl glycidyl ether, p-vinylbenzyl glycidyl ether, α-methyl-o-vinylbenzyl glycidyl ether, α-methyl-m-vinylbenzyl glycidyl ether, α-methyl-p-vinylbenzyl glycidyl ether, 2,3-diglycidyloxymethyl styrene, 2,4-diglycidyloxymethyl styrene, 2,5-diglycidyloxymethyl styrene, 2,6-diglycidyloxymethyl styrene, 2,3,4-triglycidyloxymethyl styrene, 2,3,5-triglycidyloxymethyl styrene, 2,3,6-triglycidyloxymethyl styrene, 3,4,5-triglycidyloxymethyl styrene, 2,4,6-triglycidyloxymethyl styrene, and 3,4-epoxycyclohexyl methyl methacrylate.

The weight average molecular weight (Mw) of the photoreactive resin (A) is not particularly limited, and is preferably 1,000 or more and 100,000 or less in terms of polystyrene as measured by gel permeation chromatography (GPC). When the Mw is within the above-mentioned range, satisfactory coating properties are obtained, and solubility of the photosensitive resin composition in a developing solution in pattern formation is also satisfactory.

In the photosensitive resin composition of the present invention, the content of the photoreactive resin (A) is not particularly limited, and can be arbitrarily selected according to the desired film thickness and application. The content is preferably from 20 to 60 parts by weight based on 100 parts by weight of the solid content. When the content is within the above-mentioned range, the developability and the properties of the obtained cured film are well-balanced.

[(B) Epoxy Compound]

The photosensitive resin composition of the present invention contains (B) an epoxy compound represented by the following general formula (1) (hereinafter also referred to as (B) an epoxy compound):

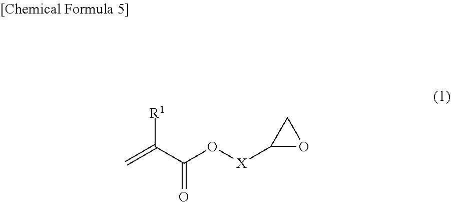

wherein X represents a group having an alkylene oxide having 4 to 10 carbon atoms or a group derived from a bisphenol, and R¹ represents a hydrogen atom or a methyl group.

The epoxy compound (B) has a (meth)acryloyl group, and the (meth)acryloyl group undergoes the addition reaction with the photoreactive resin (A) by light irradiation. Further, the epoxy group and the polyfunctional epoxy compound (C) described later are crosslinked with each other by thermal curing, so that the obtained cured film has a high crosslinking density and is excellent in chemical resistance and substrate adhesiveness.

From the viewpoint of photoreactivity, X in the general formula (1) is preferably an alkylene oxide group having 4 or more carbon atoms. From the viewpoint of chemical resistance and substrate adhesiveness of the obtained cured film, X in the general formula (1) is preferably an alkylene oxide group having 10 or less carbon atoms or a group derived from a bisphenol. Since X is a long-chain group, the epoxy compound has a high degree of freedom of the reaction, and easily undergoes a photoreaction or a crosslinking reaction of the epoxy group. Even if one of the (meth)acryloyl group and the epoxy group undergoes the reaction and is incorporated into the other component, the other one of the reactive groups is likely to be exposed since X is a long-chain group, and the cured film tends to have a high crosslinking density.

Specific examples of the epoxy compound (B) include 4-hydroxybutyl (meth)acrylate glycidyl ether, bisphenol A monoglycidyl ether mono(meth)acrylate, and bisphenol F monoglycidyl ether mono(meth)acrylate. The epoxy compound (B) may be one compound or a combination of two or more compounds.

In the photosensitive resin composition of the present invention, the content of the epoxy compound (B) is not particularly limited, and can be arbitrarily selected according to the desired film thickness and application. The content is preferably from 1 to 30 parts by weight based on 100 parts by weight of the solid content. The content is more preferably 5 parts by weight or more and 20 parts by weight or less.

[(C) Polyfunctional Epoxy Compound]

The photosensitive resin composition of the present invention contains (C) a polyfunctional epoxy compound represented by the following general formula (2) (hereinafter also referred to as (C) a polyfunctional epoxy compound):

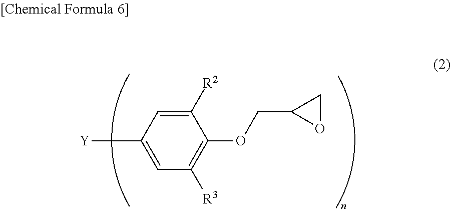

wherein a linking group Y represents a hydrocarbon group having 1 to 15 carbon atoms, R² and R³ each independently represent a hydrogen atom or a hydrocarbon group having 1 to 6 carbon atoms, and n represents an integer of 3 or 4. A plurality of R² and a plurality of R³ may each be the same or different. Examples of the linking group Y are shown below:

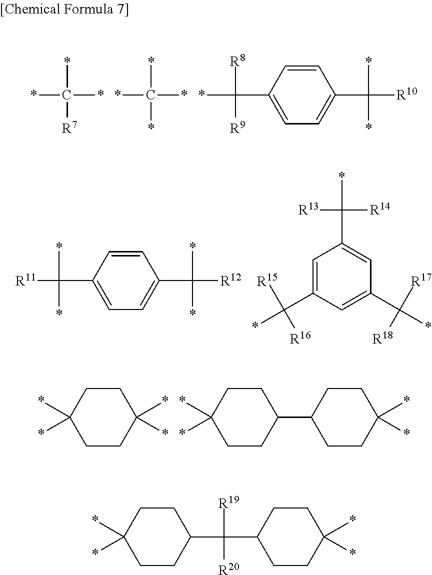

wherein * represents a linking site, and R⁷ to R²⁰ each represent a hydrogen atom or a hydrocarbon group.

Preferable examples of the linking group Y and preferable examples of the polyfunctional epoxy compound (C) corresponding to the examples of the linking group. Y are shown in the following formulae.

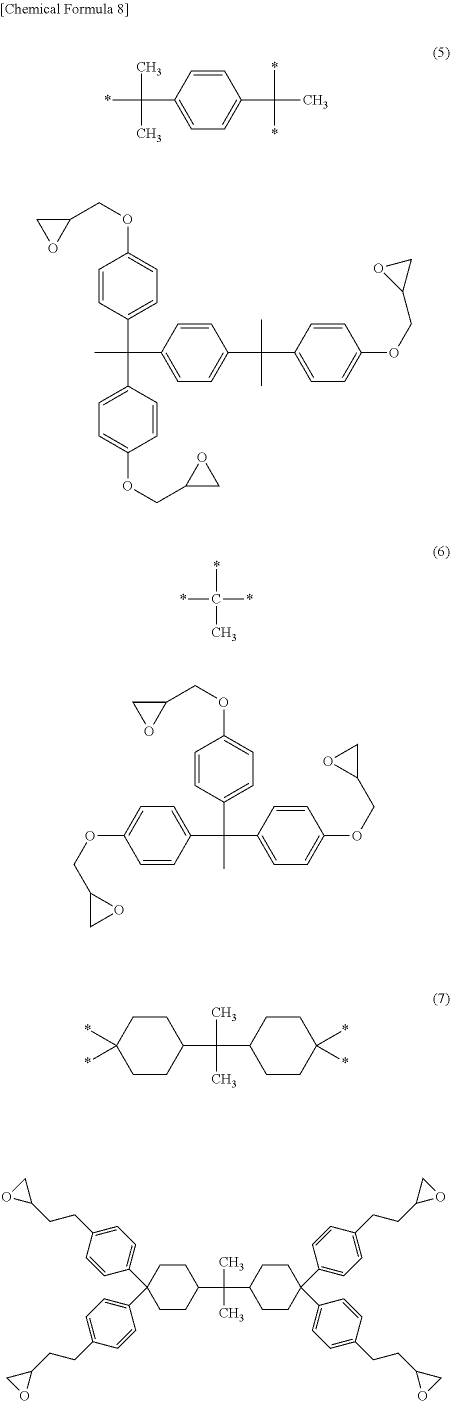

Among these, the linking group Y represented by the formula (5) is particularly preferably used from the viewpoint of the balance between alkali solubility of the photosensitive resin composition and chemical resistance of the obtained cured film.

Since n in the general formula (2) is 3 or 4, the obtained cured film is improved in chemical resistance. If n is 2 or less, the obtained cured film fails to have sufficient chemical resistance due to its too low a crosslinking density, whereas if n is 5 or more, the photosensitive resin composition has poor solubility in a developing solution and is deteriorated in patternability. That is, the polyfunctional epoxy compound (C) is tri- or tetrafunctional. The polyfunctional epoxy compound (C) may be one compound or a combination of two or more compounds.

Although the polyfunctional epoxy compound (C) alone can provide an effect of improving the chemical resistance, a combination of the polyfunctional epoxy compound (C) with the epoxy compound (B) increases the crosslinking density and significantly improves the chemical resistance.

The content of the polyfunctional epoxy compound (C) is not particularly limited, and can be arbitrarily selected according to the desired film thickness and application. The content is preferably from 0.5 to 20 parts by weight based on 100 parts by weight of the solid content. The content is more preferably 2 parts by weight or more and 15 parts by weight or less.

[(D) Photopolymerization Initiator]

The photosensitive resin composition of the present invention contains (D) a photopolymerization initiator. The photopolymerization initiator (D) is decomposed by and/or reacts with light (including ultraviolet rays and electron beams) to generate radicals.

Specific examples of the photopolymerization initiator include combinations of a photoreducing dye such as 2-methyl-[4-(methylthio)phenyl]-2-morpholinopropan-1-one, 2-dimethylamino-2-(4-methylbenzyl)-1-(4-morpholin-4-yl-phenyl)-butan-1-one, 2-benzyl-2-dimethylamino-1-(4-morpholinophenyl)-butanone-1,2,4,6-trimethylbenzoyl phenylphosphine oxide, bis(2,4,6-trimethylbenzoyl)-phenylphosphine oxide, bis(2,6-dimethoxybenzoyl)-(2,4,4-trimethylpentyl)-phosphine oxide, 1-phenyl-1,2-propanedione-2-(o-ethoxycarbonyl)oxime, 1,2-octanedione, 1-[4-(phenylthio)-2-(O-benzoyloxime)], 1-phenyl-1,2-butadione-2-(o-methoxycarbonyl)oxime, 1,3-diphenylpropanetrione-2-(o-ethoxycarbonyl)oxime, ethanone, 1-[9-ethyl-6-(2-methylbenzoyl)-9H-carbazol-3-yl]-, 1-(0-acetyloxime), 4,4-bis(dimethylamino)benzophenone, 4,4-bis(diethylamino)benzophenone, p-dimethylamino ethyl benzoate, 2-ethylhexyl-p-dimethylamino benzoate, p-diethylamino ethyl benzoate, diethoxy acetophenone, 2-hydroxy-2-methyl-1-phenylpropan-1-one, benzyldimethylketal, 1-(4-isopropylphenyl)-2-hydroxy-2-methylpropan-1-one, 4-(2-hydroxyethoxy)phenyl-(2-hydroxy-2-propyl)ketone; 1-hydroxycyclohexyl-phenyl ketone, benzoin, benzoin methyl ether, benzoin ethyl ether, benzoin isopropyl ether, benzoin isobutyl ether, benzophenone, methyl o-benzoylbenzoate, 4-phenylbenzophenone, 4,4-dichlorobenzophenone, hydroxybenzophenone, 4-benzoyl-4′-methyl-diphenylsulfide, alkylated benzophenone, 3,3′,4,4′-tetra(t-butylperoxycarbonyl)benzophenone, 4-benzoyl-N,N-dimethyl-N-[2-(1-oxo-2-propenyloxy)ethyl]benzene methanaminium bromide, (4-benzoylbenzyl)trimethylammonium chloride, 2-hydroxy-3-(4-benzoylphenoxy)-N,N,N-trimethyl-1-propene aminium chloride monohydrate, 2-isopropylthioxanthone, 2,4-dimethylthioxanthone, 2,4-diethylthioxanthone, 2,4-dichlorothioxanthone, 2-hydroxy-3-(3,4-dimethyl-9-oxo-9H-thioxanthen-2-yloxy)-N,N,N-trimethyl-1-propanaminium chloride, 2,2′-bis(o-chlorophenyl)-4,5,4′,5′-tetraphenyl-1,2-biimidazole, 10-butyl-2-chloroacridone, 2-ethylanthraquinone, benzyl, 9,10-phenanthrenequinone, camphorquinone, methylphenylglyoxy ester, η5-cyclopentadienyl-η6-cumenyl-iron(1+)-hexafluorophosphate(1−), a diphenyl sulfide derivative, bis(η5-2,4-cyclopentadien-1-yl)-bis(2,6-difluoro-3(1H-pyrrol-1-yl)-phenyl)titanium, thioxanthone, 2-methylthioxanthone, 2-chlorothioxanthone, 4-benzoyl-4-methylphenylketone, dibenzylketone, fluorenone, 2,3-diethoxyacetophenone, 2,2-dimethoxy-2-phenyl-2-phenylacetophenone, 2-hydroxy-2-methylpropiophenone, p-t-butyldichloroacetophenone, benzylmethoxyethyl acetal, anthraquinone, 2-t-butylanthraquinone, 2-aminoanthraquinone, β-chloroanthraquinone, anthrone, benzanthrone, dibenzosuberone, methylene anthrone, 4-azidobenzal acetophenone, 2,6-bis(p-azidobenzylidene)cyclohexane, 2,6-bis(p-azidobenzylidene)-4-methylcyclohexanone, naphthalenesulfonyl chloride, quinolinesulfonyl chloride, N-phenylthioacridone, benzothiazole disulfide, triphenylphosphine, tetrabrominated carbon, tribromophenylsulfone, benzoyl peroxide, eosin, and methylene blue, with a reducing agent such as ascorbic acid and triethanolamine. One of them or a combination of two or more of them can be used.

The content of the photopolymerization initiator (D) is not particularly limited, and is preferably from 0.05 to 20 parts by weight or less based on 100 parts by weight of the solid content. The content is more preferably 2 parts by weight or more and 15 parts by weight or less.

[(E) Phosphorus-Containing Compound]

The photosensitive resin composition of the present invention may contain (E) a phosphorus-containing compound. Incorporation of the phosphorus-containing compound (5) improves adhesiveness with a metal base material, particularly a metal base material containing molybdenum. The phosphorus-containing compound (E) is preferably a compound represented by the following general formula (4):

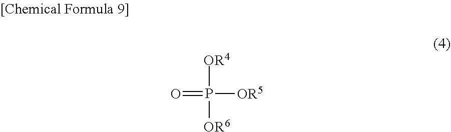

wherein R⁴ to R⁶ each independently represent a hydrogen atom or a hydrocarbon group having 1 to 6 carbon atoms.

Specific examples of the phosphorus-containing compound (E) include methyl phosphate, ethyl phosphate, propyl phosphate, butyl phosphate, phenyl phosphate, dimethyl phosphate, diethyl phosphate, dipropyl phosphate, dibutyl phosphate, diphenyl phosphate, trimethyl phosphate, triethyl phosphate, tripropyl phosphate, tributyl phosphate, and triphenyl phosphate.

The content of the phosphorus-containing compound (E) is not particularly limited, and is preferably from 0.01 to 10 parts by weight based on 100 parts by weight of the solid content. The content is more preferably 0.05 parts by weight or more and 5 parts by weight or less.

The photosensitive resin composition of the present invention may contain a polyfunctional monomer for the purpose of adjusting the sensitivity of the resin composition. A “polyfunctional monomer” refers to a compound having at least two ethylenically unsaturated double bonds in the molecule. In consideration of ease of radical polymerization, a polyfunctional monomer having a (meth)acryloyl group is preferable. Specific examples of the polyfunctional monomer are listed below, but the polyfunctional monomer is not limited thereto.

Examples of a polymerizable compound having two (meth)acryloyl groups in the molecule include 1,3-butanediol di(meth)acrylate, 1,4-butanediol di(meth)acrylate, 1,6-hexanediol di(meth)acrylate, 1,9-nonanediol di(meth)acrylate, 1,10-decanediol di(meth)acrylate, neopentyl glycol di(meth)acrylate, 2,4-dimethyl-1,5-pentanediol di(meth)acrylate, butylethyl propanediol di(meth)acrylate, ethoxylated cyclohexane methanol di (meth) acrylate, polyethylene glycol di(meth)acrylate, oligoethylene glycol di(meth)acrylate, dipropylene glycol di(meth)acrylate, polypropylene glycol di(meth)acrylate, 2-ethyl-2-butyl-propanediol di(meth)acrylate, 2-ethyl-2-butyl-butanediol di(meth)acrylate, hydroxypivalic acid neopentyl glycol di(meth)acrylate, alkylene oxide-modified bisphenol A di(meth)acrylate, alkylene oxide-modified bisphenol F di(meth)acrylate, oligopropylene glycol di(meth)acrylate, tricyclodecane di(meth)acrylate, bis(2-hydroxyethyl)isocyanurate di(meth)acrylate, 9,9-bis[4-(2-(meth)acryloyloxyethoxy)phenyl]fluorene, 9,9-bis[4-(2-(meth)acryloyloxyethoxy)-3-methylphenyl]fluorene, 9,9-bis[4-(2-(meth)acryloyloxypropoxy)-3-methylphenyl]fluoren e, and 9,9-bis[4-(2-(meth)acryloyloxyethoxy)-3,5-dimethylphenyl]fluorene.

Examples of a polymerizable compound having three (meth)acryloyl groups in the molecule include trimethylolpropane tri(meth)acrylate, trimethylolethane tri(meth)acrylate, trimethylolpropane alkylene oxide-modified tri(meth)acrylate, pentaerythritol tri-(meth)acrylate, dipentaerythritol tri(meth)acrylate, trimethylolpropane tri((meth)acryloyloxypropyl)ether, glycerol tri(meth)acrylate, tris(2-hydroxyethyl)isocyanurate tri(meth)acrylate, isocyanuric acid alkylene oxide-modified tri(meth)acrylate, propionic acid dipentaerythritol tri(meth)acrylate, tri((meth)acryloyloxyethyl)isocyanurate, hydroxy pivalaldehyde-modified dimethylol propane tri(meth)acrylate, sorbitol tri(meth)acrylate, propoxylated trimethylolpropane tri(meth)acrylate, and ethoxylated glycerol triacrylate.

Examples of a polymerizable compound having four (meth)acryloyl groups in the molecule include pentaerythritol tetra(meth)acrylate, sorbitol tetra(meth)acrylate, ditrimethylol propane tetra(meth)acrylate, dipentaerythritol propionate tetra (meth) acrylate, and ethoxylated pentaerythritol tetra(meth)acrylate.

Examples of a polymerizable compound having five (meth)acryloyl groups in the molecule include sorbitol. penta(meth)acrylate and dipentaerythritol penta(meth)acrylate.

Examples of a polymerizable compound having six (meth)acryloyl groups in the molecule include dipentaerythritol hexa(meth)acrylate, sorbitol hexa(meth)acrylate, and caprolactone-modified dipentaerythritol hexa(meth)acrylate.

Examples of a polymerizable compound having seven (meth)acryloyl groups in the molecule include tripentaerythritol heptaacrylate.

Examples of a polymerizable compound having eight (meth)acryloyl groups in the molecule include tripentaerythritol octaacrylate. One of them or a combination of two or more of them can be used.

The photosensitive resin composition of the present invention may contain various curing agents that promote curing of the resin composition or make curing of the resin composition easy. The curing agent is not particularly limited, and known curing agents can be used. Specific examples thereof include nitrogen-containing organic substances, silicone resin curing agents, various metal alcoholates, various metal chelate compounds, isocyanate compounds and polymers thereof, methylolated melamine derivatives, and methylolated urea derivatives. The photosensitive resin composition may contain two or more of them. Among them, metal chelate compounds, methylolated melamine derivatives, and methylolated urea derivatives are preferably used from the viewpoint of stability of the curing agent and workability of the obtained coating film.

The photosensitive resin composition of the present invention may contain an ultraviolet absorber. Incorporation of the ultraviolet absorber improves the lightfastness of the obtained cured film, and improves the resolution after development in applications requiring patterning. The ultraviolet absorber is not particularly limited, and known ultraviolet absorbers can be used. The ultraviolet absorber is preferably a benzotriazole compound, a benzophenone compound, or a triazine compound from the viewpoint of transparency and non-coloring properties.

Examples of the ultraviolet absorber made of a benzotriazole compound include 2-(2H benzotriazol-2-yl)phenol, 2-(2H-benzotriazol-2-yl)-4,6-tert-pentylphenol, 2-(2H benzotriazol-2-yl)-4-(1,1,3,3-tetramethylbutyl)phenol, 2(2H-benzotriazol-2-yl)-6-dodecyl-4-methylphenol, and 2-(2′-hydroxy-5′-methacryloxyethylphenyl)-2H-benzotriazole. Examples of the ultraviolet absorber made of a benzophenone compound include 2-hydroxy-4-methoxybenzophenone. Examples of the ultraviolet absorber made of a triazine compound include 2-(4,6-diphenyl-1,3,5 triazin-2-yl)-5-[(hexyl)oxy]-phenol.

The photosensitive resin composition of the present invention may contain a polymerization inhibitor. Incorporation of an appropriate amount of a polymerization inhibitor improves the resolution after development. The polymerization inhibitor is not particularly limited, and known polymerization inhibitors can be used. Examples thereof include di-t-butylhydroxytoluene, butylhydroxyanisole, hydroquinone, 4-methoxyphenol, 1,4-benzoquinone, and t-butylcatechol. Examples of commercially available polymerization inhibitors include “IRGANOX 1010 (trade name)”, “IRGANOX 1035 (trade name)”, “IRGANOX 1076 (trade name)”, “IRGANOX 1098 (trade name)”, “IRGANOX 1135 (trade name)”, “IRGANOX 1330 (trade name)”, “IRGANOX 1726 (trade name)”, “IRGANOX 1425 (trade name)”, “IRGANOX 1520 (trade name)”, “IRGANOX 245 (trade name)”, “IRGANOX 259 (trade name)”, “IRGANOX 3114 (trade name)”, “IRGANOX 565 (trade name)”, and “IRGANOX 295 (trade name)” (all manufactured by BASF Japan Ltd.).

The photosensitive resin composition of the present invention may contain a solvent. The photosensitive resin composition of the present invention can suitably contain a solvent having a boiling point of 250° C. or lower under atmospheric pressure, and a plurality of these solvents may be used. If any solvent remains in the cured film obtained by thermally curing the photosensitive resin composition of the present invention, the cured film loses chemical resistance and substrate adhesiveness with the lapse of time. Accordingly, it is preferable that a solvent having a boiling point of 150° C. or lower under atmospheric pressure account for 50, parts by weight or more of all the solvents in the photosensitive resin composition.

Examples of the solvent having a boiling point of 150° C. or lower under atmospheric pressure include ethanol, isopropyl alcohol, 1-propyl alcohol, 1-butanol, 2-butanol, isopentyl alcohol, ethylene glycol monomethyl ether, ethylene glycol dimethyl ether, ethylene glycol monoethyl ether, methoxymethyl acetate, propylene glycol monomethyl ether, propylene glycol monoethyl ether, propylene glycol monomethyl ether acetate, propylene glycol monopropyl ether, ethylene glycol monomethyl ether acetate, 1-methoxypropyl-2-acetate, acetol, acetylacetone, methyl isobutyl ketone, methyl ethyl ketone, methyl propyl ketone, methyl lactate, toluene, cyclopentanone, cyclohexane, n-heptane, benzene, methyl acetate, ethyl acetate, propyl acetate, isobutyl acetate, butyl acetate, isopentyl acetate, pentyl acetate, 3-hydroxy-3-methyl-2-butanone, 4-hydroxy-3-methyl-2-butanone, and 5-hydroxy-2-pentanone.

Examples of the solvent having a boiling point of 150 to 250° C. under atmospheric pressure include ethylene glycol diethyl ether, ethylene glycol mono-n-butyl ether, ethylene glycol mono-tert-butyl ether, propylene glycol mono n-butyl ether, propylene glycol mono t-butyl ether, 2-ethoxyethyl acetate, 3-methoxy-1-butanol, 3-methoxy-3-methylbutanol, 3-methoxy-3-methylbutyl acetate, 3-methoxybutyl acetate, 3-ethoxypropionic acid ethyl ester, propylene glycol monomethyl ether propionate, dipropylene glycol methyl ether, diisobutyl ketone, diacetone alcohol, ethyl lactate, butyl lactate, dimethylformamide, dimethylacetamide, γ-butyrolactone, γ-valerolactone, δ-valerolactone, propylene carbonate, N-methylpyrrolidone, cyclohexanone, cycloheptanone, diethylene glycol monobutyl ether, and ethylene glycol dibutyl ether.

The content of the solvent is not particularly limited, and the solvent can be used in any amount depending on the coating method or the like. For example, in the case of forming a film by spin coating, in general, the content of the solvent is 50 parts by weight or more and 95 parts by weight or less of the total amount of the photosensitive resin composition.

The photosensitive resin composition of the present invention may contain various surfactants such as various fluorochemical surfactants and silicone surfactants in order to improve the flowability during the coating. The type of the surfactant is not particularly limited, and examples thereof include fluorochemical surfactants such as “MEGAFACE (registered trademark)” “F142D (trade name)”, “F172 (trade name)”, “F173 (trade name)”, “F183 (trade name)”, “F445 (trade name)”, “F470 (trade name)”, “F475 (trade name)”, and “F477 (trade name)” (all manufactured by Dainippon Ink and Chemicals, Incorporated), and “NBX-15 (trade name)” and “FTX-218 (trade name)” (manufactured by NEOS COMPANY LIMITED); silicone surfactants such as “BYK-333 (trade name)”, “BYK-301 (trade name)”, “BYK-331 (trade name)”, “BYK-345 (trade name)”, and “BYK-307 (trade name)” (manufactured by BYK Japan KK); polyalkylene oxide surfactants; and poly(meth)acrylate surfactants. The photosensitive resin composition may contain two or more of them.

The photosensitive resin composition of the present invention may contain additives such as dissolution inhibitors, stabilizers, and antifoaming agents, if necessary.

The solid content concentration of the photosensitive resin composition of the present invention is not particularly limited, and any solvent or solute can be used in any amount depending on the coating method or the like. For example, in the case of forming a film by spin coating as described later, in general, the solid content concentration is 5 parts by weight or more and 50 parts by weight or less.

A typical method for manufacturing the photosensitive resin composition of the present invention will be described below.

For example, the polyfunctional epoxy compound (C), the photopolymerization initiator (D), and other additives are added to an arbitrary solvent and dissolved by stirring, then the photoreactive resin (A) containing an ethylenically unsaturated group and a carboxyl group and the epoxy compound (B) are added to the resulting solution, and the resulting mixture is further stirred for 20 minutes to 3 hours. The resulting solution is filtered to give a photosensitive resin composition.

A method for forming a cured film using the photosensitive resin composition of the present invention will be described with reference to examples. The photosensitive resin composition of the present invention is applied to a base substrate by a known method such as microgravure coating, spin coating, dip coating, curtain flow coating, roll coating, spray coating, or slit coating, and then prebaked with a heating device such as a hot plate or an oven. The photosensitive resin composition is prebaked at a temperature in the range of 50 to 130° C. for 30 seconds to 30 minutes. After the prebaking, the film of the photosensitive resin composition preferably has a thickness of 0.1 to 15 μm.

After the prebaking, the film is exposed to light with an exposure machine such as a stepper, a mirror projection mask aligner (MPA), or a parallel light mask aligner (PLA). The exposure intensity is about 10 to 4000 J/m² (in terms of the exposure amount at a wavelength of 365 nm), and the film is irradiated with light of this intensity with or without a desired mask. There are no limitations on the exposure light source, and ultraviolet rays such as i-line, g-line, and h-line, KrF (wavelength: 248 nm) laser, ArF (wavelength: 193 nm) laser and the like can be used.

Then, the exposed portion is dissolved by development to give a negative pattern. As for the development method, the film is preferably immersed in a developing solution for 5 seconds to 10 minutes by a method such as showering, dipping, or paddling. The developing solution may be a known alkali developing solution. Specific examples thereof include aqueous solutions containing one or more of inorganic alkalis such as hydroxides, carbonates, phosphates, silicates, and borates of alkali metals; amines such as 2-diethylaminoethanol, monoethanolamine, and diethanolamine; and quaternary ammonium salts such as tetramethylammonium hydroxide and choline. After the development, the developed film is preferably rinsed with water, and may then be dry-baked at a temperature in the range of 50 to 130° C.

Then, the film is heated with a heating device such as a hot plate or an oven at a temperature in the range of 80 to 150° C. for about 15 minutes to 1 hour.

The thickness of the cured film obtained from the photosensitive resin composition of the present invention is not particularly limited, and is preferably from 0.1 to 15 μm. Further, a film having a thickness of 1.5 μm preferably has a transmittance of 85% or more. The transmittance refers to the transmittance at a wavelength of 400 nm. The transmittance can be adjusted by selecting the exposure amount and the thermal curing temperature.

A laminate including a base material and a cured film obtained by curing the photosensitive resin composition of the present invention on the base material can be used as various protective films such as protective films for touch panels, various hard coat materials, flattening films for TFTs, overcoats for color filters, antireflection films, and passivation films, optical filters, insulating films for touch panels, insulating films for TFTs, photo spacers for color filters, and the like. In particular, the laminate can be suitably used as an insulating film for a touch panel since the laminate has high chemical resistance and substrate adhesiveness.

Further, a cured film obtained by curing the photosensitive resin composition of the present invention can be suitably used as a metal wiring protective film since the cured film has high adhesiveness to a metal base material. The metal to be protected is not particularly limited, and examples thereof include copper, silver, aluminum, chromium, molybdenum, titanium, ITO, indium zinc oxide (IZO), aluminum-doped zinc oxide (AZO), and ZnO₂.

Since the photosensitive resin composition of the present invention is curable at a low temperature of 150° C. or lower, it can be suitably used, for example, in a base material having a low heat resistance temperature, such as a display panel or a film.

### EXAMPLES

Hereinafter, the present invention will be described more specifically by way of examples. The present invention is not limited to these examples. Among the compounds used in synthesis examples and examples, those abbreviated are shown below.

PGMEA: Propylene glycol monomethyl ether acetate

PGME: Propylene glycol monomethyl ether

MAM: Molybdenum/aluminum/molybdenum laminated film

### Synthesis Example 1 Synthesis of Cardo Resin (A-1) Solution (a-1)

In a 500-ml flask, 92.2 g of 9,9-bis(4-glycidyloxyphenyl)fluorene (“PG-100 (trade name)” manufactured by Osaka Gas Chemicals Co., Ltd.), 14.4 g of acrylic acid, 0.32 g of tetrabutylammonium acetate, 0.26 g of 2,6-di-tert-butylcatechol, and 110 g of PGMEA were charged, and the resulting mixture was stirred at 120° C. for 9 hours. Then, 34.8 g of biphenyltetracarboxylic dianhydride and 50 g of PGMEA were added, and the resulting mixture was further stirred at 120° C. for 5 hours. Then, the mixture was cooled to room temperature, and PGMEA was added so that the resulting cardo resin (A-1) solution would have a solid content concentration of 40 wt % to give a cardo resin (A-1) solution (a-1) as a PGMEA solution. The cardo resin (A-1) solution (a-1) had a weight average molecular weight in terms of polystyrene of 5,700 as measured by the GPC method.

### Synthesis Example 2 Synthesis of Acrylic Resin (A-2) Solution (a-2)

In a 500-ml flask, 3 g of 2,2′-azobis (isobutyronitrile) and 50 g of PGMEA were charged. Then, 30 g of methacrylic acid, 22.48 g of styrene, and 25.13 g of cyclohexyl methacrylate were added to the flask. The liquid mixture was stirred at room temperature for a while, the atmosphere in the flask was replaced with nitrogen, and the mixture was heated and stirred at 70° C. for 5 hours. Then, 15 g of glycidyl methacrylate, 1 g of dimethylbenzylamine, 0.2 g of p-methoxyphenol, and 100 g of PGMEA were added to the resulting solution, and the resulting mixture was heated and stirred at 90° C. for 4 hours. Then, the mixture was cooled to room temperature, and PGMEA was added so that the resulting acrylic resin (A-2) solution would have a solid content concentration of 40 wt % to give an acrylic resin (A-2) solution (a-2) as a PGMEA solution. The acrylic resin (A-2) solution (a-2) had a weight average molecular weight in terms of polystyrene of 13,500 as measured by the GPC method.

### Synthesis Example 3 Preparation of Cardo Resin (A-1) Solution (a-3)

“WR-301 (trade name)” (manufactured by ADEKA Corporation), which is a PGMEA solution of the cardo resin (A-1) containing an ethylenically unsaturated group and a carboxyl group, is a product having a solid content concentration of 45 wt %, a solid content acid value of 100, and a weight average molecular weight in terms of polystyrene of 5,500 as measured by the GPC method. “WR-301” (100 g) was weighed, and 12.5 g of PGMEA was added thereto with stirring. In this way, a cardo resin (A-1) solution (a-3) having a solid content concentration of 40 wt % was obtained.

### Comparative Synthesis Example 1 Acrylic Resin Solution (a-4) Containing No Ethylenically Unsaturated Bond

In a 500-ml flask, 3 g of 2,2′-azobis (isobutyronitrile) and 50 g of PGMEA were charged. Then, 20 g of methacrylic acid, 32.67 g of styrene, and 39.93 g of cyclohexyl methacrylate were added to the flask. The liquid mixture was stirred at room temperature for a while, the atmosphere in the flask was replaced with nitrogen, and the mixture was heated and stirred at 70° C. for 5 hours. Then, 0.2 g of p-methoxyphenol and 100 g of PGMEA were added to the mixture. Then, the mixture was cooled to room temperature, and PGMEA was added so that the resulting acrylic resin solution would have a solid content concentration of 40 wt % to give an acrylic resin solution (a-4) as a PGMEA solution. The acrylic resin solution (a-4) had a weight average molecular weight in terms of polystyrene of 16,500 as measured by the GPC method.

The epoxy compounds (B) and the polyfunctional epoxy compounds (C) used in the examples are shown below.

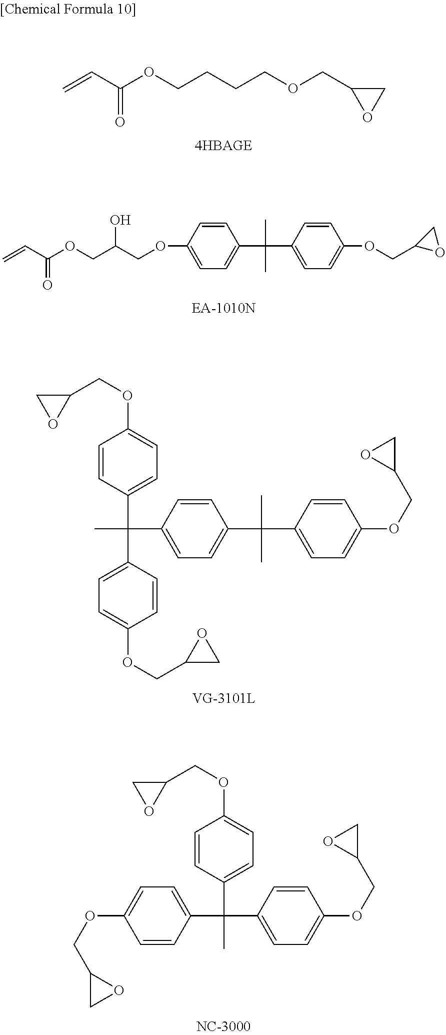 [SMILES: C=CC(=O)OCCCCOCC1CO1 ; C=CC(=O)OCC(O)COc1ccc(C(C)(C)c2ccc(OCC3CO3)cc2)cc1 ; CC(C)(c1ccc(OCC2CO2)cc1)c1ccc(C(C)(c2ccc(OCC3CO3)cc2)c2ccc(OCC3CO3)cc2)cc1 ; CC(c1ccc(OCC2CO2)cc1)(c1ccc(OCC2CO2)cc1)c1ccc(OCC2CO2)cc1]

4HBAGE (trade name) (Manufactured by Nippon Kasei Chemical Company Limited)

EA-1010N (trade name) (manufactured by Shin Nakamura Chemical Co., Ltd.)

VG-3101L (trade name) (manufactured by Printec Corporation)

NC-3000 (trade name) (manufactured by Nippon Kayaku Co., Ltd.)

(1) Evaluation of Patternability

The photosensitive resin composition was applied with a spin coater (“1H-360S (trade name)” manufactured by Mikasa Co., Ltd.) to a silicon wafer by spin coating at an arbitrary rotational speed, and the substrate was prebaked on a hot plate (“SCW-636 (trade name)” manufactured by Dainippon Screen Mfg. Co., Ltd.) at 100° C. for 2 minutes to produce a film having a thickness of 2 μm.

Then, the produced film was exposed to a super high-pressure mercury lamp as a light source using a parallel light mask aligner (“PLA-501F (trade name)” manufactured by Canon Inc.) through a gray scale mask for sensitivity measurement at a gap of 100 μm. Then, the film was subjected to shower development with a 0.045 wt % aqueous potassium hydroxide solution using an automatic developing apparatus (“AD-2000 (trade name)” manufactured by TAKIZAWA SANGYO K.K.) for 60 seconds, and then rinsed with water for 30 seconds.

After the exposure and development, the exposure amount at which 30-μm line-and-space patterns were formed at a width ratio of 1:1 (hereinafter referred to as the optimum exposure amount) was taken as the sensitivity, and the minimum pattern dimension after the development at the optimum exposure amount was taken as the resolution.

(2) Evaluation of Adhesion

The produced photosensitive resin composition was applied with a spin coater (“1H-360S (trade name)” manufactured by Mikasa Co., Ltd.) to a glass substrate having ITO or a MAM formed by sputtering on the surface (hereinafter referred to as an “ITO substrate” or a “MAM substrate”) by spin coating at an arbitrary rotational speed, and the substrate was prebaked on a hot plate (“SCW-636 (trade name)” manufactured by Dainippon Screen Mfg. Co., Ltd.) at 100° C. for 2 minutes to produce a film having a thickness of 2 μm. The produced film was exposed to a super high-pressure mercury lamp as a light source using a parallel light mask aligner (“PLA-501F (trade name)” manufactured by Canon Inc.), and cured in the air in an oven (“IHPS-222 (trade name)” manufactured by ESPEC CORP.) at 150° C. for 1 hour to produce a cured film having a thickness of 1.5 μm. As for the cured film thus obtained, adhesion between the cured film and ITO or the MAM was evaluated according to JIS “K 5600-5-6 (established on Apr. 20, 1999)”.

On the surface of the cured film formed on the glass substrate, two sets, which were perpendicular to each other, of 11 parallel straight lines were inscribed with a cutter knife at an interval of 1 mm in such a manner that the lines reached the base of the glass substrate to produce 100 squares each having a size of 1 mm×1 mm. Apiece of cellophane adhesive tape (width: 18 mm, adhesive force: 3.7 N/10 mm) was stuck to the inscribed surface of the cured film, and the tape was brought into close contact with the cured film by rubbing with an eraser (JIS S 6050 accepted product). Then, one end of the tape was held and the tape was peeled off instantaneously in a direction perpendicular to the substrate, and the number of squares remaining on the substrate was visually counted. The adhesion was rated according to the following criteria of the area of peeled squares. Grade 4 or higher was regarded as acceptable.

5: Area of peeled squares is 0%

4: Area of peeled squares is 5% or less

3: Area of peeled squares is from 5 to 14%

2: Area of peeled squares is from 15 to 34%

1: Area of peeled squares is from 35% to 64%

0: Area of peeled squares is from 65% to 100%

(3) Evaluation of Chemical Resistance (Resistance to N300)

A cured film having a thickness of 1.5 μm was formed on an ITO substrate or a MAM substrate in the same manner as described in (2) Evaluation of adhesion. The cured film was immersed in a resist stripping solution “N300 (trade name)” (manufactured by Nagase ChemteX Corporation) at a predetermined temperature for 5 minutes, and then adhesion between the cured film and ITO or the MAM was evaluated according to JIS “K 5600-5-6 (established on Apr. 20, 1999). When the area of peeled squares was 5% or less, it was judged that the photosensitive resin composition has chemical resistance under the relevant conditions.

Conditions 1: 40° C., 5 minutes

Conditions 2: 60° C., 5 minutes

Conditions 3: 80° C., 5 minutes

The chemical resistance was evaluated in the following four grades depending on the conditions under which the photosensitive resin composition had no problem in chemical resistance. Grade 2 or higher was regarded as acceptable.

3: Photosensitive resin composition had chemical resistance under all of conditions 1, 2, and 3

2: Photosensitive resin composition had chemical resistance under conditions 1 and 2

1: Photosensitive resin composition had chemical resistance under only conditions 1

0: Photosensitive resin composition had no chemical resistance under all conditions

### Example 1

Under a yellow light, 0.188 g of (D) a photopolymerization initiator, 1,2-octanedione, 1-[4-(phenylthio)-2-(O-benzoyloxime)] (“IRGACURE OXE-01 (trade name)” manufactured by BASF Japan Ltd.), 1.200 g of a 1 wt % PGMEA solution of 4-t-butylcatechol (hereinafter referred to as TBC), and 0.320 g of (C) a polyfunctional epoxy compound represented by the general formula (2), “TECHMORE VG-3101L (trade name)” (manufactured by Printec Corporation, corresponding to the compound of chemical formula (5)) were dissolved in 9.600 g of PGME and 2.116 g of PGMEA. To the resulting solution, 0.4000 g of a 1 wt % PGMEA solution of a silicone surfactant “BYK-333 (trade name)” (manufactured by BYK Japan KK) (corresponding to a concentration of 200 ppm) was added, and the resulting mixture was stirred. To the mixture, 1.200 g of dipentaerythritol hexaacrylate (“KAYARAD (registered trademark)” DPHA (trade name) manufactured by Nippon Kayaku Co., Ltd.), 0.480 g of (B) an epoxy compound represented by the general formula (1), 4-hydroxybutyl acrylate glycidyl ether (“4HBAGE (trade name)” manufactured by Nippon Kasei Chemical Company Limited), and 4.500 g of the cardo resin (A-1) solution (a-1) were added, and the resulting mixture was stirred. Then, the mixture was filtered with a 0.45 μm filter to give a photosensitive resin composition (P-1). As for the obtained photosensitive resin composition (P-1), (1) Evaluation of patternability, (2) Evaluation of adhesion, and (3) Evaluation of chemical resistance were carried out. The results are shown in Table 2.

### Example 2

The same operation as in Example 1 was carried out except that 4.000 g of the acrylic resin (A-2) solution (a-2) was used in place of the cardo resin (A-1) solution (a-1), and the amounts of the epoxy compound (B) represented by the general formula (1), “4HBAGE (trade name)” and the polyfunctional epoxy compound (C) represented by the general formula (2), “TECHMORE VG-3101L (trade name)” were changed to 0.400 g and 0.600 g, respectively, to give a photosensitive resin composition (P-2). The obtained photosensitive resin composition (P-2) was evaluated in the same manner as in Example 1.

### Example 3

The same operation as in Example 1 was carried out except that 4.000 g of the cardo resin (A-1) solution (a-3) was used in place of the cardo resin (A-1) solution (a-1), and the amounts of the epoxy compound (B) represented by the general formula (1), “4HBAGE (trade name)” and the polyfunctional epoxy compound (C) represented by the general formula (2), “TECHMORE VG-3101L (trade name)” were changed to 0.800 g and 0.200 g, respectively, to give a photosensitive resin composition (P-3). The obtained photosensitive resin composition (P-3) was evaluated in the same manner as in Example 1.

### Example 4

The same operation as in Example 1 was carried out except that 0.200 g of bisphenol A monoglycidyl ether monoacrylate (“EA-1010N (trade name)” manufactured by Shin Nakamura Chemical Co., Ltd.) was used in place of the epoxy compound (B) represented by the general formula (1), “4HBAGE (trade name)”, and the amount of the polyfunctional epoxy compound (C) represented by the general formula (2), “TECHMORE VG-3101L (trade name)” was changed to 0.600 g to give a photosensitive resin composition (P-4). The obtained photosensitive resin composition (P-4) was evaluated in the same manner as in Example 1.

### Example 5

The same operation as in Example 2 was carried out except that “EA-1010N (trade name)” as described above was used in place of the epoxy compound (B) represented by the general formula (1), “4HBAGE (trade name)”, and the amounts of the acrylic resin (A-2) solution (a-2) and the polyfunctional epoxy compound (C) represented by the general formula (2), “TECHMORE VG-3101L (trade name)” were changed to 4.500 g and 0.400 g, respectively, to give a photosensitive resin composition (P-5). The obtained photosensitive resin composition (P-5) was evaluated in the same manner as in Example 1.

### Example 6

The same operation as in Example 1 was carried out except that “NC-3000 (trade name)” (manufactured by Nippon Kayaku Co., Ltd., corresponding to the compound of chemical formula (6)) was used in place of the polyfunctional epoxy compound (C) represented by the general formula (2), “TECHMORE VG-3101L (trade name)” to give a photosensitive resin composition (P-6). The obtained photosensitive resin composition (P-6) was evaluated in the same manner as in Example 1.

### Example 7

The same operation as in Example 1 was carried out except that 0.016 g of (E) a phosphorus-containing compound, trimethyl phosphate was further added to give a photosensitive resin composition (P-7). The obtained photosensitive resin composition (P-7) was evaluated in the same manner as in Example 1.

### Example 8

The same operation as in Example 8 was carried out except that 0.040 g of diphenyl phosphate was used in place of the phosphorus-containing compound (E), trimethyl phosphate to give a photosensitive resin composition (P-8). The obtained photosensitive resin composition (P-8) was evaluated in the same manner as in Example 1.

### Example 9

The same operation as in Example 2 was carried out except that 0.080 g of (E) a phosphorus-containing compound, trimethyl phosphate was further added to give a photosensitive resin composition (P-9). The obtained photosensitive resin composition (P-9) was evaluated in the same manner as in Example 1.

### Example 10

A member for a touch panel was produced according to the following procedure.

(1) Production of Transparent Electrode (ITO Film)

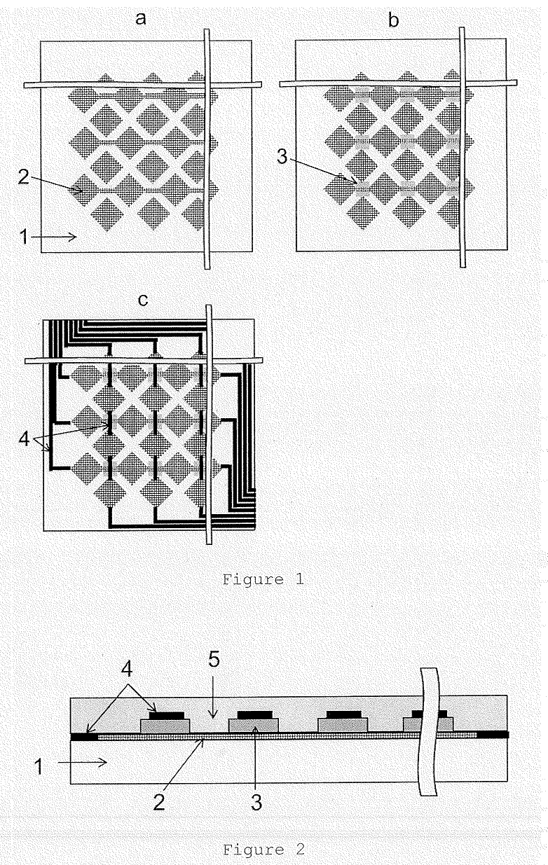

On a glass substrate having a thickness of about 1 mm, an ITO film having a thickness of 150 nm and a surface resistance of 15Ω/□ was deposited by sputtering with a sputtering system HSR-521A (manufactured by Shimadzu Corporation) at an RF power of 1.4 kW and a degree of vacuum of 6.65×10⁻¹ Pa for 12.5 minutes. Then, a positive photoresist (“OFPR-800” manufactured by TOKYO OHKA KOGYO CO., LTD.) was applied to the ITO film and prebaked at 80° C. for 20 minutes to give a resist film having a thickness of 1.1 μm. After the obtained film was subjected to pattern exposure with a super high-pressure mercury lamp through a mask using a PLA, the film was subjected to shower development with a 2.38 wt % aqueous TMAH solution using an automatic developing apparatus for 90 seconds, and then rinsed with water for 30 seconds. Then, the ITO film was etched by immersion in a HCl/HNO₃/H₂O=18/4.5/77.5 (weight ratio) mixed solution at 25° C. for 80 seconds, and the photoresist was removed by treatment with a stripping solution “N-300 (trade name)” at 40° C. for 120 seconds to give a glass substrate having a 150-nm thick patterned ITO film (reference sign 2 in FIGS. 1 and 2) (the glass substrate corresponds to FIG. 1a).

(2) Production of Insulating Film

On the glass substrate obtained in (1) (corresponding to FIG. 1a), an insulating film (reference sign 3 in FIGS. 1 and 2) was produced with the photosensitive resin composition (P-7) according to the procedure in the method for evaluation.

(3) Production of wiring electrode (MAM wiring) On the glass substrate obtained in (2) (corresponding to FIG. 1b), MAM wiring (reference sign 4 in FIGS. 1 and 2) was produced by the same procedure as in (1) Production of ITO film except that molybdenum and aluminum were used as the target, and that a H₃PO₄/HNO₃/CH₃COOH/H₂O=65/3/5/27 (weight ratio) mixed solution was used as an etchant.

(4) Production of Protective Film

On the glass substrate obtained in (3) (corresponding to FIG. 1c), a protective film was produced with the photosensitive resin composition (P-7) according to the procedure in the method for evaluation. A conduction test of the connected part was carried out with a tester, and conduction of an electric current was confirmed (corresponding to FIG. 2).

### Comparative Example 1

The same operation as in Example 1 was carried out except that the acrylic resin solution (a-4) containing no ethylenically unsaturated bond was used in place of the cardo resin (A-1) solution (a-1) to give a photosensitive resin composition (P-10). The obtained photosensitive resin composition (P-10) was evaluated in the same manner as in Example 1.

### Comparative Example 2

The same operation as in Example 1 was carried out except that the epoxy compound (B) represented by the general formula (1), “4HBAGE (trade name)” was not added to give a photosensitive resin composition (P-11). The obtained photosensitive resin composition (P-11) was evaluated in the same manner as in Example 1.

### Comparative Example 3

The same operation as in Example 1 was carried out except that the polyfunctional epoxy compound (C) represented by the general formula (2), “TECHMORE VG-3101L (trade name)” was not added to give a photosensitive resin composition (P-12). The obtained photosensitive resin composition (P-12) was evaluated in the same manner as in Example 1.

### Comparative Example 4

The same operation as in Example 1 was carried out except that glycidyl methacrylate (hereinafter referred to as GMA) was used in place of the epoxy compound (B) represented by the general formula (1), “4HBAGE (trade name)” to give a photosensitive resin composition (P-13). The obtained photosensitive resin composition (P-13) was evaluated in the same manner as in Example 1.

### Comparative Example 5

The same operation as in Example 1 was carried out except that a bifunctional epoxy compound “jER834 (trade name)” (manufactured by Mitsubishi Chemical Corporation, bisphenol A epoxy resin) was used in place of the polyfunctional epoxy compound (C) represented by the general formula (2), “TECHMORE VG-3101L (trade name)” to give a photosensitive resin composition (P-14). The obtained photosensitive resin composition (P-14) was evaluated in the same manner as in Example 1.

### Comparative Example 6

The same operation as in Example 1 was carried out except that 3-glycidoxypropyl trimethoxysilane (“KBM-403 (trade name)” manufactured by Shin-Etsu Chemical Co., Ltd.) was used in place of the epoxy compound (B) represented by the general formula (1), “4HBAGE (trade name)” to give a photosensitive resin composition (P-15). The obtained photosensitive resin composition (P-15) was evaluated in the same manner as in Example 1.

TABLE 1

| | | Constituent | | | | | | | | |
|---|---|---|---|---|---|---|---|---|---|---|
| | | | | | | (E) | | | | |
| | | (A) | (B) | (C) | (D) | Phosphorus- | | | | |
| | | Photoreactive | Epoxy | Polyfunctional | Photopolymerization | containing | | | | |
| | No. | resin | compound | epoxy compound | initiator | compound | Other additives | | | |
| Example 1 | P-1 | a-1 | 4HBAGE | VG-3101L | OXE-01 | — | DPHA | TBC | BYK-333 | PGME/ |
| | | (45) | (12) | (8) | (4.7) | | (30) | (0.3) | (200 ppm) | PGMEA |
| Example 2 | P-2 | a-2 | 4HBAGE | VG-3101L | OXE-01 | — | DPHA | TBC | BYK-333 | PGME/ |
| | | (40) | (10) | (15) | (4.7) | | (30) | (0.3) | (200 ppm) | PGMEA |
| Example 3 | P-3 | a-3 | 4HBAGE | VG-3101L | OXE-01 | — | DPHA | TBC | BYK-333 | PGME/ |
| | | (40) | (20) | (5) | (4.7) | | (30) | (0.3) | (200 ppm) | PGMEA |
| Example 4 | P-4 | a-1 | EA-1010N | VG-3101L | OXE-01 | — | DPHA | TBC | BYK-333 | PGME/ |
| | | (45) | (5) | (15) | (4.7) | | (30) | (0.3) | (200 ppm) | PGMEA |
| Example 5 | P-5 | a-2 | EA-1010N | VG-3101L | OXE-01 | — | DPHA | TBC | BYK-333 | PGME/ |
| | | (45) | (10) | (10) | (4.7) | | (30) | (0.3) | (200 ppm) | PGMEA |
| Example 6 | P-6 | a-1 | 4HBAGE | NC-3000 | OXE-01 | — | DPHA | TBC | BYK-333 | PGME/ |
| | | (45) | (12) | (8) | (4.7) | | (30) | (0.3) | (200 ppm) | PGMEA |
| Example 7 | P-7 | a-1 | 4HBAGE | VG-3101L | OXE-01 | Trimethyl | DPHA | TBC | BYK-333 | PGME/ |
| | | (45) | (12) | (8) | (4.7) | phosphate | (30) | (0.3) | (200 ppm) | PGMEA |
| | | | | | | (0.4) | | | | |
| Example 8 | P-8 | a-1 | 4HBAGE | VG-3101L | OXE-01 | Diphenyl | DPHA | TBC | BYK-333 | PGME/ |
| | | (45) | (12) | (8) | (4.7) | phosphate | (30) | (0.3) | (200 ppm) | PGMEA |
| | | | | | | (1) | | | | |
| Example 9 | P-9 | a-2 | 4HBAGE | VG-3101L | OXE-01 | Trimethyl | DPHA | TBC | BYK-333 | PGME/ |
| | | (40) | (10) | (15) | (4.7) | phosphate | (30) | (0.3) | (200 ppm) | PGMEA |
| | | | | | | (2) | | | | |
| Comparative | P-10 | a-4 | 4HBAGE | VG-3101L | OXE-01 | — | DPHA | TBC | BYK-333 | PGME/ |
| Example 1 | | (45) | (12) | (8) | (4.7) | | (30) | (0.3) | (200 ppm) | PGMEA |
| Comparative | P-11 | a-1 | — | VG-3101L | OXE-01 | — | DPHA | TBC | BYK-333 | PGME/ |
| Example 2 | | (45) | | (8) | (4.7) | | (30) | (0.3) | (200 ppm) | PGMEA |
| Comparative | P-12 | a-1 | 4HBAGE | — | OXE-01 | — | DPHA | TBC | BYK-333 | PGME/ |
| Example 3 | | (45) | (12) | | (4.7) | | (30) | (0.3) | (200 ppm) | PGMEA |
| Comparative | P-13 | a-1 | GMA | VG-3101L | OXE-01 | — | DPHA | TBC | BYK-333 | PGME/ |
| Example 4 | | (45) | (12) | (8) | (4.7) | | (30) | (0.3) | (200 ppm) | PGMEA |
| Comparative | P-14 | a-1 | 4HBAGE | jER-834 | OXE-01 | — | DPHA | TBC | BYK-333 | PGME/ |
| Example 5 | | (45) | (12) | (8) | (4.7) | | (30) | (0.3) | (200 ppm) | PGMEA |
| Comparative | P-15 | a-1 | KBM-403 | VG-3101L | OXE-01 | — | DPHA | TBC | BYK-333 | PGME/ |
| Example 6 | | (45) | (12) | (8) | (4.7) | | (30) | (0.3) | (200 ppm) | PGMEA |

TABLE 2

| | | (1) Patternability | | | (2) Adhesion | | (3) Chemical resistance | |
|---|---|---|---|---|---|---|---|---|
| | No. | Sensitivity | | Resolution | ITO | MAM | ITO | MAM |
| Example 1 | P-1 | 80 | mJ | 10 μm | 5 | 5 | 3 | 2 |
| Example 2 | P-2 | 100 | mJ | 15 μm | 5 | 4 | 2 | 2 |
| Example 3 | P-3 | 80 | mJ | 10 μm | 5 | 5 | 2 | 2 |
| Example 4 | P-4 | 100 | mJ | 15 μm | 5 | 5 | 3 | 3 |
| Example 5 | P-5 | 120 | mJ | 20 μm | 5 | 5 | 3 | 2 |
| Example 6 | P-6 | 80 | mJ | 15 μm | 5 | 5 | 2 | 2 |
| Example 7 | P-7 | 80 | mJ | 10 μm | 5 | 5 | 3 | 3 |
| Example 8 | P-8 | 80 | mJ | 10 μm | 5 | 5 | 3 | 3 |
| Example 9 | P-9 | 100 | mJ | 15 μm | 5 | 5 | 3 | 3 |
| Comparative | P-10 | 200 | mJ | 30 μm | 3 | 4 | 0 | 0 |
| Example 1 | | | | | | | | |
| Comparative | P-11 | 120 | mJ | 20 μm | 5 | 4 | 1 | 0 |
| Example 2 | | | | | | | | |
| Comparative | P-12 | 100 | mJ | 10 μm | 4 | 4 | 0 | 0 |
| Example 3 | | | | | | | | |
| Comparative | P-13 | 150 | mJ | 10 μm | 5 | 5 | 1 | 1 |
| Example 4 | | | | | | | | |
| Comparative | P-14 | 50 | mJ | 30 μm | 5 | 5 | 2 | 1 |
| Example 5 | | | | | | | | |
| Comparative | P-15 | 180 | mJ | 50 μm | 5 | 4 | 1 | 0 |
| Example 6 | | | | | | | | |

A cured film obtained by curing the photosensitive resin composition of the present invention can be suitably used in various hard coat films such as protective films for touch panels, insulating films for touch sensors, flattening films for TFTs intended for liquid crystal and organic EL displays, metal wiring protective films, insulating films, antireflection films, antireflection films, optical filters, overcoats for color filters, column materials and the like.

### DESCRIPTION OF REFERENCE SIGNS

a: Top view after formation of transparent electrode
b: Top view after formation of insulating film
c: Top view after formation of wiring electrode
1: Glass substrate
2: Transparent electrode
3: Insulating film
4: Wiring electrode
5: Protective film

1. A photosensitive resin composition comprising the following (A) to (D):
(A) a photoreactive resin containing an ethylenically unsaturated group and a carboxyl group;
(B) an epoxy compound represented by the following general formula (1): 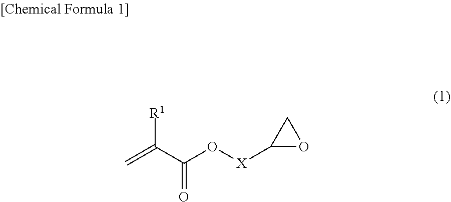
wherein X represents a group having an alkylene oxide having 4 to 10 carbon atoms or a group derived from a bisphenol, and R¹ represents a hydrogen atom or a methyl group;
(C) a polyfunctional epoxy compound represented by the following general formula (2): 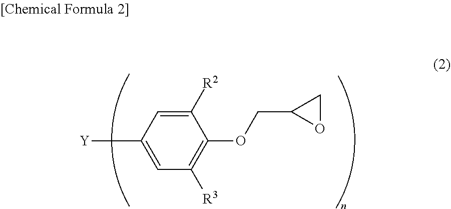
wherein a linking group Y represents a hydrocarbon group having 1 to 15 carbon atoms, R² and R³ each independently represent a hydrogen atom or a hydrocarbon group having 1 to 6 carbon atoms, and n represents an integer of 3 or 4; and
(D) a photopolymerization initiator.

2. The photosensitive resin composition according to claim 1, wherein (A) is a cardo resin having two or more structures represented by the following general formula (3) as repeating units and containing an ethylenically unsaturated group and a carboxyl group:

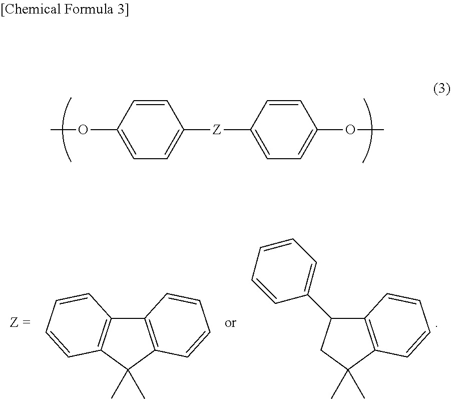

3. The photosensitive resin composition according to claim 1 or 2, wherein the linking group Y in the general formula (2) has a structure represented by the following formula: 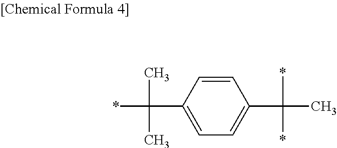
wherein * represents a linking site.

4. The photosensitive resin composition according to claim 1, further comprising (E) a phosphorus-containing compound.

5. The photosensitive resin composition according to claim 4, wherein the phosphorus-containing compound (E) is a compound represented by the following general formula (4): 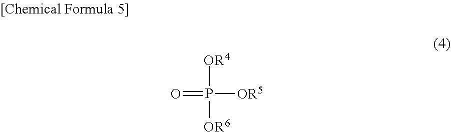
wherein R⁴ to R⁶ each independently represent a hydrogen atom or a hydrocarbon group having 1 to 6 carbon atoms.

6. A cured film that is a cured product of the photosensitive resin composition according to claim 1.

7. A laminate comprising a base material and the cured film according to claim 6 on the base material.

8. The laminate according to claim 7, wherein the base material has a metal wire containing at least one metal selected from molybdenum, titanium, and chromium.

9. The laminate according to claim 7, wherein the base material is a display panel.

10. A member for a touch panel, comprising the laminate according to claim 7.

11. The member for a touch panel according to claim 10, wherein the cured film in the laminate is an interlayer insulating film.

12. A method for manufacturing a cured film, comprising the steps of:
applying the photosensitive resin composition according to claim 1 to a base material; and
heating the photosensitive resin composition at 80 to 150° C. in this order.
